(19) United States
(12) Patent Application Publication
(10) Pub. No.: US 2026/0303052 A1
(43) Pub. Date: Oct. 1, 2026

(54) IMPEDANCE MATCHER

(71) Applicant: DAIHEN Corporation, Osaka (JP)

(72) Inventor: Shuji OMAE, Osaka (JP)

(21) Appl. No.: 19/631,031

(22) Filed: Mar. 27, 2026

(30) Foreign Application Priority Data
Mar. 31, 2025 (JP) 2025-059196

(51) Int. Cl. H03H 7/38; H01J 37/32; H02J 9/06

(52) U.S. Cl. CPC H03H 7/38; H01J 37/32183; H02J 9/06

(57) ABSTRACT

A matching controller stores information on electrode positions of variable capacitors and in the storage as OFF-time position information at a time of change of the state from the ON state to the OFF state, gives a command signal to drivers and so that the electrode position is shifted to a predetermined position (minimum position in terms of structure) after the state change from the OFF state to the ON state, estimates the information on the electrode position at a time of the state change from the OFF state to the ON state as the ON-time position information based on a change amount of the information on the positional relationship of the electrodes until a positional relationship of the electrodes is changed to a predetermined positional relationship, and discerns whether a difference regarding the OFF-time position information and the ON-time position information is within a prescribed range.

### CROSS-REFERENCE TO RELATED APPLICATIONS

This application is based upon and claims the benefit of priority from Japanese Patent Application No. 2025-059196, filed on Mar. 31, 2025, the entire contents of which are incorporated herein by reference.

### FIELD

The present disclosure relates to an impedance matcher.

### BACKGROUND

For example, a high frequency power supply system used in a plasma processing apparatus supplies high frequency power having a fundamental frequency in a Radio Frequency (RF) band (RF band) from a high frequency power source to a load (for example, a plasma processing apparatus).

In addition, there is provided an impedance matcher (also denoted as an impedance matching apparatus) between the high frequency power source and the load. The impedance matcher performs an operation of matching impedance between the high frequency power source and the load by adjusting a variable value (for example, capacitance or inductance) of an internal variable impedance element so as to decrease the power value of reflected wave power on a high frequency power source side (for example, the input end) in the impedance matcher.

The operation of changing the variable value of the variable impedance element to match the impedance in this manner is denoted as a matching operation.

As disclosed in JP 2008-251976 A, JP 2007-158438 A, and JP 2009-010190 A, a variable capacitor or a variable inductor is used as the variable impedance element, for example.

In the variable capacitor, the positional relationship of electrodes is changeable by a driver such as a motor, making it possible to change the capacitance (electrostatic capacitance) by changing the positional relationship regarding the electrodes. In addition, in the variable inductor, the positional relationship of windings is changeable by a driver such as a motor, making it possible to change the inductance by changing the positional relationship regarding the windings. That is, it is possible to change reactance values such as capacitance and inductance of the variable impedance element.

This makes it possible to adjust the load-side impedance when the load side is viewed from the high frequency power source side (for example, the input end) in the impedance matcher.

Since the structure of changing the positional relationship regarding the electrodes or regarding the windings of the variable impedance element is a mechanical structure, the change in the positional relationship causes occurrence of mechanical wear. This leads to a mechanical life of the variable impedance element. Since the variable impedance element does not operate after reaching its mechanical life, there is a need to replace the variable impedance element in accordance with use conditions.

### SUMMARY

The reactance value of the variable impedance element has individual differences. Therefore, when the variable impedance element is replaced, it is desirable to change the setting value of the impedance matcher in accordance with the reactance value of the variable impedance element.

In a case where the variable impedance element is replaced by a manufacturer or an agent, there is no problem because the setting value of the impedance matcher is changed in accordance with the reactance value of the replaced variable impedance element. However, in a case where the variable impedance element is replaced in a place other than the manufacturer or the agent, the setting value of the impedance matcher described above remains unchanged. This might lead to a failure in accurate matching operation at the time of actual operation, or to breakdown.

The present disclosure provides an impedance matcher capable of estimating whether a variable impedance element has been replaced non-regularly when the variable impedance element has been replaced non-regularly by a person other than a manufacturer or an agent.

### BRIEF DESCRIPTION OF THE DRAWINGS

FIG. 1 is a diagram illustrating a configuration example of a high frequency power supply system;

FIG. 2 is a diagram illustrating a circuit configuration example of a power transmitter 40;

FIG. 3 is a diagram illustrating another configuration example of the matching circuit; and

FIG. 4 is a flowchart for illustrating a method of estimating whether a variable impedance element has been replaced non-regularly.

### DETAILED DESCRIPTION

Hereinafter, an embodiment of an impedance matcher according to the present disclosure will be described with reference to the drawings.

### Embodiment

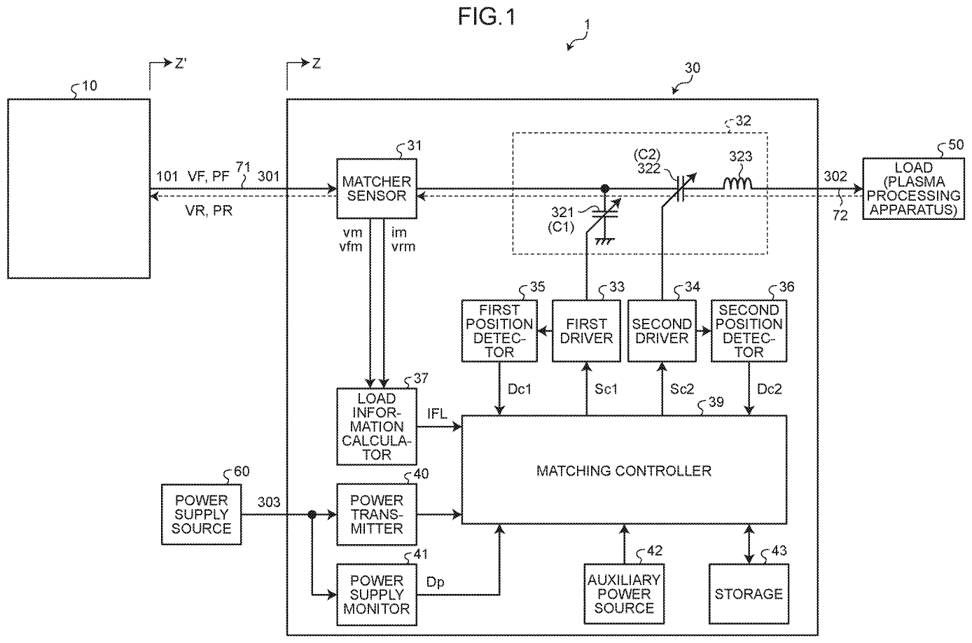

FIG. 1 is a diagram illustrating a configuration example of a high frequency power supply system.

A high frequency power supply system 1 is an apparatus that outputs high frequency power having a fundamental frequency (frequency of fundamental wave) in a Radio Frequency (RF) band from a high frequency power source 10, and supplies the high frequency power to a load 50 (for example, a plasma processing apparatus) via an impedance matcher 30.

Note that, in the present specification, the voltage component of the high frequency power is denoted as a high frequency voltage, and the current component of the high frequency power is denoted as a high frequency current. In addition, a high frequency voltage from the high frequency power source 10 to the load 50 is defined as a forward wave voltage VF, a high frequency voltage reflected from the load 50 side and returned to the high frequency power source 10 is defined as a reflected wave voltage VR, high frequency power from the high frequency power source 10 to the load is defined as a forward wave power PF, and high frequency power reflected from the load side and returned to the high frequency power source 10 is defined as a reflected wave power PR. In FIG. 1, reflected wave voltage VR and reflected wave power PR are indicated by broken lines.

Additionally, in the present specification, the power value of the forward wave power PF is defined as a forward wave power value pf, the power value of the reflected wave power PR is defined as a reflected wave power value pr, and the power value obtained by subtracting the reflected wave power value pr from the forward wave power value pf is defined as a load-side power value pL.

In the present specification, a reflection coefficient represented by a ratio of the reflected wave voltage VR to the forward wave voltage VF (reflected wave voltage VR/forward wave voltage VF) is denoted as ρ, and an absolute value (magnitude) of the reflection coefficient ρ is denoted as Γ. Practically, the reflection coefficient ρ is calculated using a forward wave voltage detection signal vf and a reflected wave voltage detection signal vr to be described below, by specifically calculating the reflected wave voltage detection signal vr/the forward wave voltage detection signal vf.

In addition, the high frequency power source 10 can decrease the reflected wave power value pr by changing the frequency of the forward wave power PF (forward wave voltage VF) to be output. Hereinafter, this function is denoted as “frequency matching”. When the frequency matching operation is performed, the fundamental frequency of the forward wave voltage VF is not constant but varies. However, the expression of the fundamental frequency will be used including a case where the fundamental frequency varies.

Furthermore, the high frequency power source 10 performs, in some cases, frequency modulation control in order to decrease the reflected wave power value pr caused by InterModulation Distortion (IMD), for example. The fundamental frequency of the forward wave voltage VF is not constant but varies even in the case where the frequency modulation control is performed. Still, the expression of the fundamental frequency will be used.

The high frequency power source 10 performs feedback control so as to decrease the error between the forward wave power value pf and the target power value pt. Such power control is denoted as forward wave power constant control (PF constant control). Feedback control can also be performed so as to decrease the error between the load-side power value pl and the target power value pt. Such power control is denoted as load-side power constant control (PL constant control). The following will describe a case where the forward wave power constant control is performed, as an example.

The forward wave voltage VF has, for example, a relatively high fundamental frequency suitable for generating plasma. The fundamental frequency is 40.68 MHz, for example.

Naturally, the fundamental frequency is not limited to 40.68 MHz, and may be a frequency in an industrial RF band such as 13.56 MHz or 27.12 MHz.

The forward wave voltage VF may have a relatively low fundamental frequency suitable for ion acceleration, for example The fundamental frequency in this case is 400 kHz, for example. Naturally, the fundamental frequency is not limited to 400 kHz, and may be other frequencies. In this manner, the fundamental frequency of the forward wave voltage VF can be various frequencies depending on the application.

As illustrated in FIG. 1, the high frequency power supply system 1 includes a high frequency power source 10 and an impedance matcher 30. The high frequency power supply system 1 may use a plurality of (for example, two) high frequency power sources 10. For example, there are cases of using a first high frequency power source having a fundamental frequency of the forward wave power PF (forward wave voltage VF) of 40.68 MHz and using a second high frequency power source having a fundamental frequency of the forward wave power PF (forward wave voltage VF) of 400 KHz. In this case, the first high frequency power source will supply high frequency power to the load 50 via the first impedance matcher, while the second high frequency power source will supply high frequency power to the load 50 via the second impedance matcher. However, as illustrated in FIG. 1, the present embodiment will describe an exemplary case where the high frequency power supply system 1 uses one high frequency power source 10.

The high frequency power source 10 amplifies a high frequency signal output from an oscillation unit (oscillator) (not illustrated), outputs and supplies the high frequency power (forward wave power) having an output frequency in an RF band to the load 50. The high frequency power output from the high frequency power source 10 is supplied to the load 50 via a transmission line 71, the impedance matcher 30, and a transmission line 72. The transmission line 71 can be implemented by using, for example, a coaxial cable or a coaxial tube. The transmission line 72 can be implemented by using a load connection member formed with a shielded copper plate, for example. The transmission lines 71 and 72 are different in length, etc. depending on the environment in which the high frequency power supply system 1 is applied and the use conditions.

The impedance matcher 30 matches the impedance between the high frequency power source 10 and the load 50. More specifically, for example, when the impedance (output impedance) when viewing the high frequency power source 10 side from the output end of the high frequency power source 10 is designed to be 50Ω, for example, and the high frequency power source 10 is connected to the input end of the impedance matcher 30 by the transmission line 71 having a characteristic impedance of 50Ω, the impedance matcher 30 converts the impedance when viewing the load 50 side from the high frequency power source 10 side (for example, the input end) in the impedance matcher 30 into 50Ω.

The load 50 is a plasma processing apparatus, for example. The plasma processing apparatus is an apparatus that includes a processing unit and is provided for processing (etching, CVD, etc.) a workpiece such as a wafer or a liquid crystal substrate loaded into the processing unit. In order to process a workpiece, the load 50 introduces a plasma discharge gas into the processing unit, and applies high frequency power (high frequency voltage) supplied from the high frequency power source 10 to the plasma discharge gas, allowing the plasma discharge gas described above to discharge and transition from a non-plasma state to a plasma state. The workpiece is processed using the plasma.

### Details of Impedance Matcher 30

The impedance matcher 30 includes a matcher sensor 31, a matching circuit 32, a first driver 33, a second driver 34, a first position detector 35, a second position detector 36, a load information calculation unit 37, a matching controller 39, a power transmitter 40, a power supply monitor 41, an auxiliary power source 42, and a storage 43.

Note that an input terminal and an output terminal are normally provided at the input end 301 and the output end 302 of the impedance matcher 30, respectively, although not illustrated. In addition, an input terminal for receiving power supply from an external power supply source 60 is normally provided in the housing of the impedance matcher 30, although not illustrated.

The matcher sensor 31 is provided at the input end 301 of the impedance matcher 30 (a preceding stage of the matching circuit 32), and detects information for calculating a load-side impedance Z when the load 50 side is viewed from the high frequency power source 10 side (for example, the input end 301) in the impedance matcher 30 or information for calculating a reflection coefficient p on the high frequency power source 10 side (for example, the input end 301) in the impedance matcher 30. Since the load-side impedance Z and the reflection coefficient ρ can be mutually converted, either of them may be detected.

In the case of calculating the load-side impedance Z, for example, a voltage detector and a current detector are used as the matcher sensor 31. In this case, the voltage on the high frequency power source 10 side (for example, the input end) in the impedance matcher 30 is detected by the voltage detector, and a voltage detection signal vm is output as a detection signal. In addition, a current on the high frequency power source 10 side (for example, the input end 301) in the impedance matcher 30 is detected by a current detector, and a current detection signal im is output as a detection signal. The voltage detection signal vm and the current detection signal im are output to the load information calculation unit 37.

When the reflection coefficient p on the high frequency power source 10 side (for example, the input end 301) in the impedance matcher 30 is calculated, for example, a directional coupler is used as the matcher sensor 31. In this case, the forward wave voltage VF output from the high frequency power source 10 is detected, a forward wave voltage detection signal vfm is output as a detection signal, and together with this, a reflected wave voltage VR reflected and returned from the load 50 side is detected, and a reflected wave voltage detection signal vrm is output as a detection signal. The forward wave voltage detection signal vfm and the reflected wave voltage detection signal vrm are output to the load information calculation unit 37.

Note that there may be an A/D converter (not illustrated) provided between the matcher sensor 31 and the load information calculation unit 37. Between the matcher sensor 31 and the load information calculation unit 37, there may be provided a filter for removing unnecessary signal components (for example, harmonic components). At this time, a filter method is to be appropriately selected.

The matching circuit 32 is provided between the matcher sensor 31 and the load 50. The matching circuit 32 internally includes, for example, a variable impedance element such as a variable capacitor (also denoted as a variable capacitor) capable of changing capacitance (electrostatic capacitance), and is configured to change a variable value (capacitance for variable capacitor, inductance for variable inductor) of the variable impedance element in accordance with a command from the matching controller 39 to be described below, making it possible to adjust the load-side impedance Z when the load 50 side is viewed from the high frequency power source 10 side (for example, the input end) in the impedance matcher 30.

Note that an impedance Z′ when viewing the load 50 side from the output end of the high frequency power source 10 is substantially the same as the load-side impedance Z. Strictly speaking, both are different depending on the length of the transmission line 71, etc., but in the present embodiment, it is assumed that the error is an allowable range in practical use.

In some cases, a variable inductor is provided as the variable impedance element. In addition, a driver such as a motor is provided to change a variable value of the variable impedance element in accordance with a command from the matching controller 39. In addition to the variable impedance element, an inductor having a fixed inductance value is provided in many cases. In addition, a capacitor having a fixed capacitance value is provided in some cases.

The matching circuit 32 illustrated in FIG. 1 is an example of the matching circuit.

The matching circuit 32 of FIG. 1 includes: a first variable capacitor 321 provided between the output end of the matcher sensor 31 and the ground; a second variable capacitor 322 provided between the output end of the matcher sensor 31 and the load 50; and an inductor 323 provided between the second variable capacitor and the load 50 and having a fixed inductance value. The capacitance of the first variable capacitor 321 is represented by C1, and the capacitance of the second variable capacitor 322 is represented by C2.

The first variable capacitor 321 and the second variable capacitor 322 are variable capacitors of a type that uses a driver such as a motor and changes a positional relationship of electrodes to change the capacitance. For example, as described in JP 2008-251976 A and JP 2007-158438 A, an electrode of a variable capacitor includes a fixed electrode and a movable electrode, and when a position of the movable electrode is changed using a driver such as a motor, the area of the counter electrode changes. Naturally, the variable capacitor is not limited to such a type. For example, it is also allowable to use a type in which the distance between the electrodes is changed when the position of the movable electrode is changed.

In the first variable capacitor 321 and the second variable capacitor 322, for example, the position of the movable electrode is changed by rotating a rotation shaft connected to the movable electrode by a driver such as a motor. Therefore, the position of the movable electrode can be known by detecting the rotation angle of the rotation shaft. The rotation angle of the rotation shaft can be detected using an encoder, for example. That is, the positional relationship regarding the electrodes can be detected by detecting the rotation angle of the rotation shaft.

The rotation shaft is designed to change the capacitance from a minimum value to a maximum value, for example, at 10 rotations (3600 degrees). However, in practice, in consideration of the variation in capacitance of the variable capacitor, the variable capacitor is designed to be able to perform 10+α rotations (for example, 12 rotations), and is designed to achieve a prescribed capacitance with 10 rotations out of 12 rotations.

For example, in the case of a variable capacitor having a minimum capacitance of 100 pF and a maximum capacitance of 1,300 pF as catalog values, the variable capacitor is designed to achieve the capacitance in the range 200 pF to 1,200 pF at 10 rotations. Accordingly, the ranges of 100 pF to 200 pF and 1,200 pF to 1,300 pF are not used in the matching operation. That is, when the matching operation is performed, 200 pF is the minimum capacitance, and 1,200 pF is the maximum capacitance.

Therefore, when the matching operation is performed, the rotation angle of the rotation shaft when the capacitance is 200 pF is set to 0 degree in terms of control. Practically, for example, the rotation angle rotated by +1 from the rotation angle of the rotation shaft at the time of the minimum capacitance (100 pF) in terms of structure of the variable capacitor may be set to 0 degrees in terms of control.

Similarly, the rotation angle of the rotation shaft when the capacitance is 1,200 pF is set to 3,600 degrees in terms of control. Practically, for example, the rotation angle rotated by −1 from the rotation angle of the rotation shaft at the time of the maximum capacitance (1,300 pF) in terms of structure of the variable capacitor may be set to 3600 degrees in terms of control.

Due to such a relationship, in order to set the rotation angle of the rotation shaft to 0 degrees in terms of control, it is only required to once set the rotation angle of the rotation shaft to the rotation angle (0 degrees in terms of structure) at which the rotation angle becomes the minimum capacitance in terms of structure, and then rotate the rotation shaft to 0 degrees in terms of control. When the rotation shaft is rotated so that the capacitance becomes the minimum capacitance, the rotation is structurally stopped when the rotation angle corresponding to the minimum capacitance is reached. Therefore, the rotation angle at this time is defined as 0 degrees in terms of structure.

In addition, in order to set the rotation angle of the rotation shaft to 3,600 degrees in terms of control, the rotation angle of the rotation shaft is required to once set to the rotation angle at which the capacitance becomes the maximum capacitance in terms of structure, and then set the rotation angle rotated by −1 to 3,600 degrees in terms of control. When the rotation shaft is rotated so that the capacitance becomes the maximum capacitance, the rotation is structurally stopped when the rotation angle corresponding to the maximum capacitance is reached. Therefore, the rotation angle at this time is defined as the maximum rotation angle in terms of structure.

With this configuration, the capacitance of the variable capacitor can be changed within a prescribed range.

Such an operation is performed after the variable capacitor is first incorporated, after the variable capacitor is replaced, or the like. By performing this operation, it is possible to set the relationship between the rotation angle of the rotation shaft of the variable capacitor in terms of structure and the rotation angle in terms of control.

Note that it is satisfactory that either 0 degrees in terms of control or 3600 degrees in terms of control is known. Accordingly, in the present embodiment, the following description will be given assuming that the 0 degree in terms of control is set.

The first driver 33 changes the position of the movable electrode of the first variable capacitor 321. The second driver 34 changes the position of the movable electrode of the second variable capacitor 322. The first driver 33 and the second driver 34 described above are each an example of a driver of the present invention.

The first driver 33 and the second driver 34 each include a motor and a driver for driving the motor. An output shaft of the motor is connected to the rotation shaft of the variable capacitor. When the output shaft of the motor rotates, the rotation shaft of the variable capacitor rotates to change the position of the movable electrode.

The motor is a stepping motor, for example. Naturally, it is also possible to use other types of motors (servo motors and the like) but the present embodiment will describe a case of using a stepping motor.

Here, the stepping motor is a motor that rotates by moving in units of a certain angle. The corresponding driver receives a pulse signal output from the controller as a command signal, and operates the stepping motor based on the command signal. When the stepping motor is used in this manner, the position of the movable electrode can be easily understood when being expressed by the number of steps corresponding to the number of pulse signals given to the stepping motor. For example, in a case where the stepping motor needs to be changed by 1,000 steps when the rotation angle of the rotation shaft rotates to 0 to 3,600 degrees (10 rotations), the position of the movable electrode can be expressed by 0 to 1,000 steps.

The first position detector 35 detects the rotation angle of the first driver 33, and includes an encoder, for example. The detected rotation angle is output to the matching controller 39 as rotation angle information Dc1. Similarly, the second position detector 36 detects the rotation angle of the second driver 34, and includes an encoder, for example.

The detected rotation angle is output to the matching controller 39 as rotation angle information Dc2. The first position detector 35 and the second position detector 36 are each an example of the position acquirer of the present invention.

As mentioned above, the rotation angle of the first driver 33 and the rotation angle of the second driver 34 indirectly represent the position of the movable electrode of the variable capacitor. Accordingly, by detecting the rotation angle of the first driver 33, the position of the movable electrode of the variable capacitor can be detected. When the stepping motor is used as described above, the position of the movable electrode of the variable capacitor may be managed by the number of steps.

For example, when the rotation angle of the rotation shaft is 0 degrees in terms of control, the capacitance is the minimum capacitance in terms of control. Therefore, the position of the movable electrode of the variable capacitor at this time can be set to 0 step. In addition, when the rotation angle of the rotation shaft is 3,600 degrees in terms of control, the capacitance is the maximum capacitance in terms of control. Therefore, the position of the movable electrode of the variable capacitor at this time can be set to 1,000 steps. Naturally, the 0 to 1,000 steps described above as examples are merely examples, and for example, it is also allowable to have a configuration of 0 to 5000 steps.

In addition, as can be seen from the above, the position of the movable electrode, the rotation angle of the rotation shaft of the variable capacitor, and the rotation angle of the motor individually have a correspondence relationship with the capacitance of the variable capacitor, and thus the capacitance of the variable capacitor can be estimated by detecting any of these.

In the present embodiment, as an example, the capacitance of the variable capacitor is estimated by the rotation angle of the motor. The rotation angle of the motor can be expressed by the number of steps. Accordingly, when the minimum capacitance in terms of control is 0 steps and the maximum capacitance in terms of control is 1,000 steps, the capacitance of the variable capacitor can be expressed in terms of the number of steps like 0 to 1,000 steps.

In addition, in the case of the above example, the minimum capacitance in terms of structure is a capacitance at a rotation angle obtained by +1 rotation of the motor from a rotation angle of 0 degrees in terms of control, and thus corresponds to −100 steps in terms of control. Similarly, the maximum capacitance in terms of structure is a capacitance at a rotation angle obtained by rotating the motor by +1 rotation from a rotation angle of 3,600 degrees in terms of control, and thus corresponds to 1,100 steps in terms of control.

The load information calculation unit 37 can calculate the reflection coefficient p or the load-side impedance Z based on the detection signal output from the matcher sensor 31. When these pieces of information are defined as load information IFL, the load information calculation unit 37 can output the load information IFL to the matching controller 39. It is not necessary to calculate all the load information IFL. For example, when the load-side impedance Z is not used for control, the load-side impedance Z need not be calculated.

In addition, based on the detection signal output from the matcher sensor 31, the load information calculation unit 37 can calculate and output the forward wave power value pf, the reflected wave power value pr, the load-side power value pL, and the reflection coefficient absolute value Γ. The information related to the high frequency power is information necessary for the output control of the high frequency power source 10, and can be output as monitor information to the outside, for example

In addition, the information related to the high frequency power described above can be utilized to control the impedance matcher 30. For example, the impedance matcher 30 may start the matching operation when the forward wave power value pf exceeds a prescribed threshold. Naturally, the matching operation may be started based on another signal (for example, the forward wave voltage detection signal vfm, the reflected wave voltage detection signal vrm, etc.). Note that it is not necessary to calculate all the information related to the high frequency power described above. For example, when the load-side power value pL is not used for control, the load-side power value pL need not be calculated.

Since calculation of the information described above is performed by known methods, a detailed description is omitted, but the information can be calculated as follows, for example.

### (1) Reflection Coefficient ρ

The reflection coefficient ρ can be calculated by, for example, the reflected wave voltage detection signal vr/the forward wave voltage detection signal vf. The absolute value (magnitude) of the reflection coefficient ρ is defined as a reflection coefficient absolute value Γ.

### (2) Load-Side Impedance Z

The load-side impedance Z can be calculated by, for example, the voltage detection signal vm/the current detection signal im. The load-side impedance Z can be calculated based on, for example, the magnitude of the voltage detection signal vm, the magnitude of the current detection signal im, and a phase difference θm between the voltage detection signal vm and the current detection signal im.

Note that the reflection coefficient ρ and the load-side impedance Z can be mutually converted. Therefore, only either the reflection coefficient ρ or the load-side impedance Z will be described below in some cases.

### (3) Forward Wave Power Value pf

The forward wave power value pf can be calculated by, for example, the forward wave voltage detection signal vfm^2/R (R: gain corresponding to resistance value).

### (4) Reflected Wave Power Value pr

The reflected wave power value pr can be calculated by, for example, the reflected wave voltage detection signal vrm^2//R (R: gain corresponding to resistance value).

### (5) Load-Side Power Value pL

The load-side power value pL can be calculated based on the forward wave power value pf and the reflected wave power value pr calculated above. The load-side power value pL can be calculated by, for example, the forward wave power value pf-the reflected wave power value pr (subtracting the reflected wave power value pr from the forward wave power value pf).

(6) Reflection coefficient absolute value Γ

The reflection coefficient absolute value Γ may be calculated based on the forward wave power value pf and the reflected wave power value pr. The reflection coefficient absolute value Γ may be calculated by √ (reflected wave power value pr/forward wave power value pf), for example.

The matching controller 39 performs the matching operation using the load information IFL output from the load information calculation unit 37, the rotation angle information Dc1 output from the first position detector 35, and the rotation angle information Dc2 output from the second position detector 36.

For example, the command signals Sc1 and Sc2 are output for changing the capacitance C1 of the first variable capacitor 321 and the capacitance C2 of the second variable capacitor 322 inside the matching circuit 32 so that the reflection coefficient absolute value Γ approaches the target reflection coefficient absolute value Γ0 (normally 0).

In other words, the command signals Sc1 and Sc2 for changing the capacitance C1 of the first variable capacitor 321 and the capacitance C2 of the second variable capacitor 322 are output so as to decrease the reflected wave power.

The first driver 33 and the second driver 34 rotate the rotation shafts of the first variable capacitor 321 and the second variable capacitor 322 based on the command signals Sc1 and Sc2 output from the matching controller 39. By repeating such an operation, the absolute value Γ approaches the target reflection coefficient absolute value Γ0 (normally 0). In other words, the reflected wave power decreases. By performing such an operation, the matching operation is performed.

Note that there are various methods in the matching operation. For example, the capacitance C1 of the first variable capacitor 321 and the capacitance C2 of the second variable capacitor 322, at which the reflection coefficient absolute value Γ is estimated to be closest to the target reflection coefficient absolute value Γ0 (normally 0) can be calculated, and the command signals Sc1 and Sc2 can be output to the first driver 33 and the second driver 34 with the capacitances as targets.

Even in performing such a matching operation, there are various ways of outputting the command signals Sc1 and Sc2. For example, when the difference between the current capacitance and the target capacitance is large, an intermediate capacitance between the current capacitance and the target capacitance may be set as the target capacitance. Although various other methods are disclosed, the method of the matching operation is not limited in the present embodiment.

In any case, the reflection coefficient absolute value Γ is controlled to approach the target reflection coefficient absolute value Γ0 (normally 0), in other words, controlled to decrease the reflected wave power.

In addition, the matching controller 39 can monitor whether power is supplied from the external power supply source 60 described below. For example, when a state in which power is supplied from the external power supply source 60 is defined as an ON state and a state in which power is not supplied from the external power supply source 60 is defined as an OFF state, the matching controller 39 can discern that the state is the ON state when the apparatus is in activation. In addition, the matching controller 39 can estimate whether the variable impedance element has been replaced non-regularly. This will be described later.

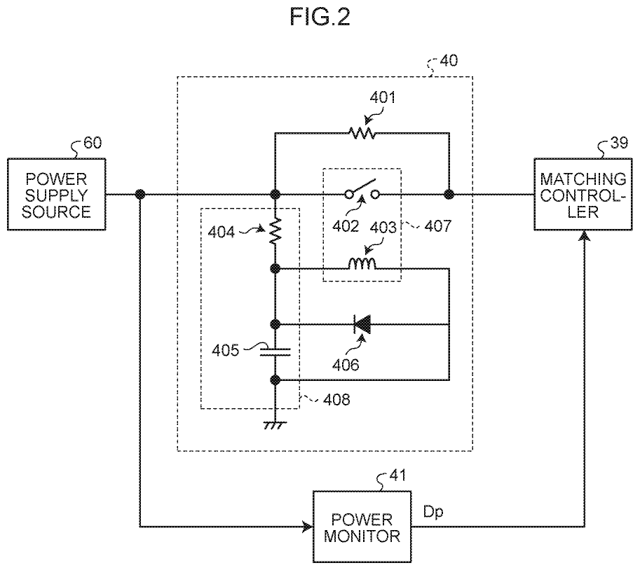

FIG. 2 is a diagram illustrating a circuit configuration example of the power transmitter 40.

The power transmitter 40 transmits power supplied from the external power supply source 60 to the controller. The power transmitter 40 is disposed between the external power supply source 60 and the matching controller 39. The power transmitter 40 includes a resistor 401, a contact portion 402, a coil 403, a resistor 404, a capacitor 405, and a diode 406. The resistor 401 is a resistor for limiting an inrush current. A portion including the contact portion 402 and the coil 403 functions as a relay circuit 407. Furthermore, a portion including the resistor 404 and the capacitor 405 functions as a delay circuit 408. The delay circuit 408 is an example of an auxiliary power source of the present invention.

In the case of the power transmitter 40 as illustrated in FIG. 2, when power is supplied from the external power supply source 60, a current flows through the coil 403 to allow the contact portion 402 of the relay circuit 407 to be in a connected state, transmitting the power from the external power supply source 60 to the matching controller 39. In contrast, when power is not supplied from the external power supply source 60, the contact portion 402 of the relay circuit 407 turns to a disconnected state, not allowing the power to be transmitted from the external power supply source 60 to the matching controller 39.

In addition, when power is supplied from the external power supply source 60, the capacitor 405 is charged. On the other hand, when power is not supplied from the external power supply source 60, the capacitor 405 is discharged to allow a current to flow through the coil 403. This current gradually decreases due to the characteristics of the delay circuit 408, but it is possible to delay the timing at which the contact portion 402 of the relay circuit 407 turns into the disconnected state. As a result, even when the power supply from the external power supply source 60 is stopped, the matching controller 39 can store information on the positional relationship regarding the electrodes or regarding the windings of the variable impedance element in the storage 43 described below.

Note that, when the external power supply source 60 is an AC power source, an AC-DC converter may be provided at an input end or an output end of the power transmitter 40, although not illustrated in FIGS. 1 and 2. In addition, the power transmitter 40 does not necessarily need to include the relay circuit 407 and the delay circuit 408 as illustrated in FIG. 2. For example, when the external power supply source 60 is an AC power source, an AC-DC converter without the relay circuit 407 or the delay circuit 408 may be used as the power transmitter 40. Furthermore, a DC-DC converter may be provided as necessary. When the external power supply source 60 is a DC power source, the DC-DC converter may be used as the power transmitter 40. In this manner, the power transmitter 40 only needs to transmit power supplied from the external power supply source 60 to the controller. However, since the delay circuit 408 functions as an auxiliary power source, in a case where the delay circuit 408 is not provided, it is necessary to provide the auxiliary power source 42 to be described below.

The power supply monitor 41 monitors whether power is supplied from the external power supply source 60 by monitoring a voltage at an input end of the power transmitter 40 (an output end of the external power supply source 60). The power supply monitor 41 is an example of a power supply state discerning unit of the present invention.

In a state where power is supplied from the external power supply source 60, the voltage at the input end of the power transmitter 40 is higher than a preset OFF discerning threshold (for example, a threshold of 3 V with respect to 5 V DC, etc.), and thus it can be seen that power is supplied from the external power supply source 60. In contrast, in a state where power is not supplied from the external power supply source 60, the voltage at the input end of the power transmitter 40 is equal to or less than the preset OFF discerning threshold, and thus it can be seen that power is not supplied from the external power supply source 60. Here, a state in which power is supplied from the external power supply source 60 is defined as an ON state, while a state in which power is not supplied from the external power supply source 60 is defined as an OFF state.

The power supply monitor 41 outputs a discerning result Dp, being a result of the discerning described above, to the matching controller 39. The discerning result Dp is 1, for example, in the ON state, and is 0, for example, in the OFF state. In this manner, by monitoring the voltage at the input end of the power transmitter 40 (the output end of the external power supply source 60), it is possible to instantaneously discern whether power is supplied from the external power supply source 60.

Note that, as mentioned above, the matching controller 39 also monitors whether power is supplied from the external power supply source 60, but it is desirable to instantaneously discern that the state has changed from the ON state to the OFF state. Therefore, it is desirable to discern that the state has changed from the ON state to the OFF state based on the discerning result Dp of the power supply monitor 41.

This is because, as described later, there is a need to store the position information of the movable electrodes of the variable impedance element and the position information of the windings in the storage 43 described above while the matching controller 39 is in the operable state when the ON state is changed to the OFF state. However, when the power transmitter 40 illustrated in FIG. 2 is used, the power supply to the matching controller 39 continues even after turning into the OFF state, and thus, the matching controller 39 cannot perform instantaneous discerning.

The auxiliary power source 42 is provided for supplying power to the matching controller 39 when power is not supplied from the external power supply source 60. For example, a commercially available battery may be used, or a power supply of a type that charges a capacitor may be used.

Even when the power supply from the external power supply source 60 is stopped, the power is supplied from the auxiliary power source 42 to the matching controller 39, making it possible for the matching controller 39 to store information on the positional relationship regarding the electrodes or regarding the windings of the variable impedance element in the storage 43 described below.

The storage 43 is a storage including nonvolatile memory, and can hold stored data even when power is not supplied, such as an EEPROM. Note that the storage 43 is an example of a storage of the present invention.

The matching controller 39 can store the position information of the movable electrode of the variable impedance element and the position information of the winding in the storage 43. Further, the matching controller 39 can read the position information stored in the storage 43. As mentioned above, the value converted into the number of steps (for example, 0 to 1,000 steps) can be used as the position information of the movable electrodes of the variable impedance element and the position information of the windings. The impedance matcher 30 also includes volatile memory (not illustrated), and can store information to be temporarily used. The matching circuit is not limited to the configuration illustrated in FIG. 1.

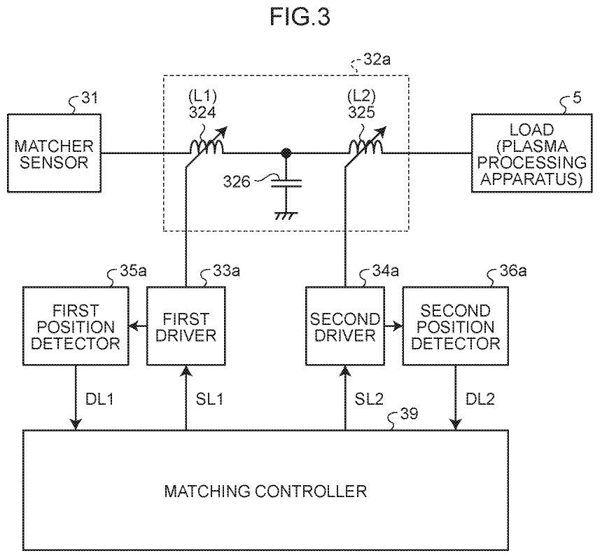

FIG. 3 is a diagram illustrating another configuration example of the matching circuit.

A matching circuit 32a of FIG. 3 includes: a first variable inductor 324 provided at the output end of the matcher sensor 31; a second variable inductor 325 provided between the output end of the first variable inductor 324 and the load 50; and a capacitor 326 provided between the output end of the first variable inductor 324 and the ground. The inductance of the first variable inductor 324 is represented by L1, and the inductance of the second variable inductor 325 is represented by L2. The capacitance of the capacitor 326 is a fixed value. In this manner, a variable inductor can also be used as the variable impedance element. In addition, FIG. 3 illustrates an example of using the capacitor 326 having a fixed capacitance value, but a variable capacitor may be used instead of the capacitor 326.

The variable inductor includes a fixed winding and a movable winding, for example, and can change inductance by changing a positional relationship of the movable winding with respect to the fixed winding. For example, a rotation shaft is connected to the movable winding, and rotating the rotation shaft by a driver such as a motor changes the positional relationship of the movable winding with respect to the fixed winding, causing a change in the inductance. That is, although there is a difference between the capacitance and the inductance, the inductance as a control target can be changed by changing the positional relationship regarding the windings by the driver such as a motor similarly to the variable capacitor.

Accordingly, as illustrated in FIG. 3, an inductance L1 of the first variable inductor 324 can be detected by changing the positional relationship regarding the windings of the first variable inductor 324 by a first driver 33a and detecting the rotation angle of the motor of the first driver 33a by the first position detector 35a. The detected rotation angle is output to the matching controller 39 as rotation angle information DL1.

Similarly, an inductance L2 of the second variable inductor 325 can be detected by changing the positional relationship regarding the windings of the second variable inductor 325 by a second driver 34a and detecting the rotation angle of the motor of the second driver 34a by the second position detector 36a. The detected rotation angle is output to the matching controller 39 as rotation angle information DL2. Note that the first driver 33a, the second driver 34a, the first position detector 35a, and the second position detector 36a have different control targets, but have configurations similar to those of the first driver 33, the second driver 34, the first position detector 35, and the second position detector 36 illustrated in FIG. 1, respectively. Therefore, the description will be omitted.

In addition, similarly to the variable capacitor, the position of the movable winding, the rotation angle of the rotation shaft of the variable inductor, and the rotation angle of the motor individually have a correspondence relationship with the inductance of the variable inductor, and thus, it is possible to estimate the inductance of the variable inductor by detecting any of these. Therefore, similarly to the variable capacitor, the inductance of the variable inductor can be expressed in terms of the number of steps, for example, 0 to 1,000 steps. Note that, although the rotation angle of the rotation shaft and the like are different between the variable inductor and the variable capacitor, concepts such as the minimum inductance in terms of structure and the minimum inductance in terms of control are similar to the minimum capacitance of the variable capacitor and the minimum capacitance in terms of control.

Note that, although FIG. 1 illustrates an example in which there are two variable capacitors in the matching circuit 32, the number of variable capacitors is not limited. For example, one variable capacitor may be provided, or three or more variable capacitors may be provided. In addition, FIG. 3 illustrates an example in which there are two variable inductors in the matching circuit 32, but the number of variable inductors is not limited. For example, one variable inductor may be provided, or three or more variable inductors may be provided. Although not illustrated, one or more variable capacitors and one or more variable inductors may be mixed in the matching circuit 32.

Next, a method of estimating whether the variable impedance element has been replaced non-regularly will be described.

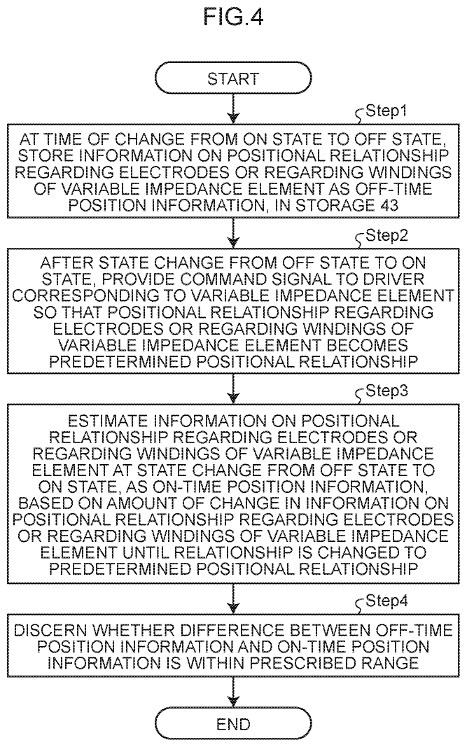

FIG. 4 is a flowchart for illustrating a method of estimating whether a variable impedance element has been replaced non-regularly. The variable impedance element may be either a variable capacitor or a variable inductor. In the flowchart, a state in which power is supplied from the external power supply source 60 is defined as an ON state, while a state in which power is not supplied from the external power supply source 60 is defined as an OFF state.

### Step 1

When the ON state has changed to the OFF state, the matching controller 39 stores information on the positional relationship regarding the electrodes or regarding the windings of the variable impedance element in the storage 43 as OFF-time position information.

Note that whether the ON state has changed to the OFF state can be discerned based on the discerning result Dp output from the power supply monitor 41. Furthermore, the information on the positional relationship regarding the electrodes or regarding the windings of the variable impedance element can be obtained based on the rotation angle information output from the position detector corresponding to the variable impedance element.

When the variable impedance element is a variable capacitor (the first variable capacitor 321 and the second variable capacitor 322) as illustrated in FIG. 1, the information on the positional relationship regarding the electrodes of the variable impedance element is information indicating the position of the movable electrode, the rotation angle of the rotation shaft of the variable capacitor, or the rotation angle of the motor.

When the variable impedance element is a variable inductor (First variable inductor 324 and second variable inductor 325) as illustrated in FIG. 3, the information on the positional relationship regarding the windings of the variable impedance element is information indicating the position of the movable winding, the rotation angle of the rotation shaft of the variable inductor, or the rotation angle of the motor.

When the variable capacitor is provided in plurality (in FIG. 1, two of the first variable capacitor 321 and the second variable capacitor 322 are provided), information on the positional relationship regarding the electrodes of individual variable impedance elements is stored in the storage 43 as OFF-time position information.

When the variable inductor is provided in plurality (in FIG. 3, two of the first variable inductor 324 and the second variable inductor 325 are provided), information on the positional relationship regarding the windings of the individual variable impedance elements is stored in the storage 43 as OFF-time position information.

In a case where one or more variable capacitors and one or more variable inductors are mixed in the matching circuit 32, information on the positional relationship regarding the electrodes or regarding the windings of the individual variable impedance elements is stored in the storage 43 as OFF-time position information.

### Step 2

After the state has changed from the OFF state to the ON state, a command signal is provided to the driver corresponding to the variable impedance element so that the positional relationship regarding the electrodes or regarding the windings of the variable impedance element becomes a predetermined positional relationship. In a case where there is a plurality of variable impedance elements, the processing is only needed to be executed for the individual variable impedance element.

Note that the predetermined positional relationship in a case where the variable impedance element is a variable capacitor is a positional relationship in which the capacitance of the variable capacitor is the minimum capacitance in terms of structure, or a positional relationship in which the capacitance of the variable capacitor is the maximum capacitance in terms of structure. In addition, the predetermined positional relationship in a case where the variable impedance element is a variable inductor is either a positional relationship in which the inductance of the variable inductor is the minimum inductance in terms of structure or a positional relationship in which the inductance of the variable inductor is the maximum inductance in terms of structure.

### Step 3

Information on the positional relationship regarding the electrodes or regarding the windings of the variable impedance element when the state is changed from the OFF state to the ON state is estimated as the ON-time position information based on the amount of change in the information on the positional relationship regarding the electrodes or regarding the windings of the variable impedance element until the change to the predetermined positional relationship described above.

For example, when the variable impedance element is the first variable capacitor 321 and the predetermined positional relationship in Step 2 is a positional relationship of the minimum capacitance in terms of structure, the motor of the first driver 33 is rotated such that the movable electrode of the first variable capacitor 321 has the minimum capacitance in terms of structure.

At this time, it is assumed that the position of the movable electrode of the first variable capacitor 321 when the state is changed from the OFF state to the ON state is a position corresponding to 500 steps in terms of control, and the difference in the positional relationship between the minimum capacitance in terms of structure and the minimum capacitance in terms of control is 100 steps. In this case, the position of the movable electrode is to change by 600 steps. Therefore, it can be seen that the ON-time position information is a position corresponding to 500 steps.

### Step 4

Discerning is performed as to whether a difference between the OFF-time position information and the ON-time position information is within a prescribed range. For example, when the prescribed range is ±10 steps, the OFF-time position information in Step 1 is 500 steps, and the ON-time position information in Step 3 is 500 steps, the difference between the OFF-time position information and the ON-time position information is 0. However, when the ON-time position information in Step 3 is 450 steps, this is out of the prescribed range, indicating that the movable electrode or the movable winding of the variable impedance element has moved in the OFF state. In this manner, when the difference between the OFF-time position information and the ON-time position information is out of the prescribed range, it can be estimated that there is a high possibility that the variable impedance element has been removed from the impedance matcher and replaced when there is no supply of power for operating the impedance matcher.

The reactance value of the variable impedance element has individual differences. Therefore, when the variable impedance element is replaced, it is necessary to change the setting value of the impedance matcher in accordance with the reactance value of the variable impedance element.

In a case where the variable impedance element is replaced by a manufacturer or an agent, there is no problem because the setting value of the impedance matcher is changed in accordance with the electrostatic capacitance of the replaced variable impedance element. However, in a case where the variable impedance element is replaced in a place other than the manufacturer or the agent, the setting value of the impedance matcher described above remains unchanged. This might lead to a failure in accurate matching operation at the time of actual operation.

Therefore, when the difference between the OFF-time position information stored in the storage and the estimated ON-time position information is not within the prescribed range, it is possible, for example, to take measures such as suppressing operation of the impedance matcher in consideration of the possibility that the impedance matcher cannot operate normally. Alternatively, an alarm can be output. Consequently, in a case where the variable impedance element is replaced non-regularly at a place other than a manufacturer or an agent, for example, the impedance matcher of the present embodiment is capable of preventing a situation in which the variable impedance element cannot perform accurate matching operation at the time of actual operation, or capable of outputting an alarm to call attention. In addition, the matching controller 39 can store information on a difference between the OFF-time position information and the ON-time position information in the storage 43.

The information to be stored includes, for example, information (1) to (3) as follows.
(1) Difference between OFF-time position information and ON-time position information for each variable impedance element (for example, the number of steps of difference)
(2) Determination result on whether difference between the OFF-time position information and the ON-time position information for each variable impedance element is within a prescribed range (for example, “normal”when the value is within the range, and “abnormal” when the value is out of the range.)
(3) Determination date and time of (2) described above (when this information is stored, a clock function is preferably provided in the impedance matcher.)

In this way, by referring to the information stored in the storage 43, it is possible to estimate whether the variable impedance element has been replaced in a place other than the manufacturer or the agent. This is because, in a case where the variable impedance element is replaced at a manufacturer, an agent, or the like, even with storage of information in which a difference between the OFF-time position information and the ON-time position information is not within a prescribed range, it is possible to recognize the fact that the replacement is a regular replacement. In this case, it is only required to cancel the abnormality.

Note that instead of storing all the pieces of information (1) to (3) described above in the storage 43, some of the pieces of information (1) to (3) described above may be stored in the storage 43. For example, the information of (2) may be stored in the storage 43. Alternatively, the information may be stored in the storage 43 when the difference between the OFF-time position information and the ON-time position information is not within the prescribed range. In addition, instead of the information for each variable impedance element, the fact that the difference between the OFF-time position information and the ON-time position information is not within a prescribed range in any variable impedance element may be stored in the storage 43.

With the impedance matcher according to the present disclosure, it is possible to estimate whether the variable impedance element has been replaced non-regularly.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An impedance matcher provided between a high frequency power source and a load, the high frequency power source being configured to supply high frequency power to the load, the impedance matcher comprising:
a matching circuit including at least one variable impedance element, the variable impedance element including electrodes and windings and having a variable positional relationship regarding the electrodes or regarding the windings;
a driver that changes the positional relationship regarding the electrodes or regarding the windings;
a position acquirer that acquires information on the positional relationship regarding the electrodes or regarding the windings;
a storage being a nonvolatile unit and configured to store information on the positional relationship regarding the electrodes or regarding the windings;
a controller;
a power supply state discerning unit that discerns whether power for operating the controller is supplied from an external power supply source; and
an auxiliary power source that supplies power to the controller when power supply from the external power supply source is stopped,
wherein, when a state in which power is supplied from the external power supply source is defined as an ON state and a state in which power is not supplied from the external power supply source is defined as an OFF state,
the controller performs operations including:
storing, in the storage, information on a positional relationship regarding the electrodes or regarding the windings, as off-state positional information, when the ON state has changed to the OFF state,
giving a command signal to the driver so that the positional relationship regarding the electrodes or regarding the windings becomes a predetermined positional relationship, after the change from the OFF state to the ON state,
estimating information on the positional relationship regarding the electrodes or regarding the windings when the state has been changed from the OFF state to the ON state as On-state positional information based on a change amount of the information on the positional relationship regarding the electrodes or regarding the windings until a change to the predetermined positional relationship; and
discerning whether a difference regarding the OFF-time position information and the ON-time position information is within a prescribed range.

2. The impedance matcher according to claim 1,
wherein, when the matching circuit includes a plurality of the variable impedance elements, discerning is performed, for each of the variable impedance elements, as to whether a difference between the OFF-time position information and the ON-time position information is within the prescribed range.

3. The impedance matcher according to claim 1,
wherein, when a voltage at an operating power input terminal connected to an external power supply source is equal to or less than an OFF discerning threshold, the power supply state discerning unit discerns that power is not supplied and discerns that the power supply state is the OFF state.

4. The impedance matcher according to claim 1,
wherein, when the controller discerns that power is supplied when the controller is in activation, the controller discerns that the power supply state is the ON state.

5. The impedance matcher according to claim 1, further comprising a relay circuit and a delay circuit provided between an external power supply source and the controller,
wherein the relay circuit is configured to:
operate a contact portion such that the contact portion connects the external power supply source and the controller to each other by passing a current to flow through a coil in the ON state, and
the delay circuit is configured to:
pass the current to flow through the coil when the ON state has changed to the OFF state to delay timing at which the contact portion shifts from a connected state to a disconnected state between the external power supply source and the controller, and supply power to the controller via the contact portion.

6. The impedance matcher according to claim 1,
wherein, when the difference between the OFF-time position information and the ON-time position information is not within the prescribed range,
the controller stores, in the storage, information indicating that the difference is not within the range.
